(19) United States
(12) Patent Application Publication
(10) Pub. No.: US 2026/0164581 A1
(43) Pub. Date: Jun. 11, 2026

(54) ELECTRONIC DEVICE INCLUDING WINDOW

(71) Applicant: KT&G CORPORATION, Daejeon (KR)

(72) Inventors: Dong Sung KIM, Seoul (KR); Youngbum KWON, Yongin-si (KR); Yong Hwan KIM, Anyang-si (KR); Hwikyeong AN, Seoul (KR)

(73) Assignee: KT&G CORPORATION, Daejeon (KR)

(21) Appl. No.: 19/316,828

(22) Filed: Sep. 2, 2025

(30) Foreign Application Priority Data
Dec. 6, 2024 (KR) 10-2024-0180337

(51) Int. Cl. H05K 5/03; A24F 40/40; A24F 40/60

(52) U.S. Cl. CPC H05K 5/03; A24F 40/40; A24F 40/60

(57) ABSTRACT

An electronic device includes a housing, a window including a key area and a display area and disposed in a housing, a first groove disposed between the key area and the display area, and a second groove disposed between the key area and the housing and including a shape that is substantially the same as a shape of the first groove.

### CROSS-REFERENCE TO RELATED APPLICATION

Pursuant to 35 U.S.C. § 119(a), this application claims the benefit of earlier filing date and right of priority to Korean Patent Application No. 10-2024-0180337, filed on Dec. 6, 2024, the contents of which are hereby incorporated by reference herein in its entirety.

### BACKGROUND

### 1. Field of the Invention

The disclosure generally relates to an electronic device including a window.

### 2. Description of the Related Art

Techniques for an electronic device including a display panel and a window have been developed. The window may be used as an interface to receive a user input. The window may be formed of a transparent material, such as glass, and the characteristics of the material may limit the user experience. The display panel and the window are also applied to an aerosol-generating device that generates an aerosol from an aerosol-generating article. The above description is information the inventor(s) acquired during the course of conceiving the present disclosure, or already possessed at the time, and is not necessarily art publicly not known before the present application was filed.

### SUMMARY

An aspect of the present disclosure may provide an electronic device in which a key area is distinguished.

An electronic device includes a housing, a window including a key area and a display area and disposed in a housing, a first groove disposed between the key area and the display area, and a second groove disposed between the key area and the housing and including a shape that is substantially the same as a shape of the first groove.

The first groove extends in a width direction of the window, and the second groove extends in the width direction of the window.

The first groove includes a first inclined surface and a second inclined surface, and the second groove includes a third inclined surface that includes a shape substantially the same as a shape of the first inclined surface and is disposed on the window and a fourth inclined surface that includes a shape substantially the same as a shape of the second inclined surface and is disposed on the housing.

The first inclined surface and the second inclined surface are disposed to be mirror-symmetrical with each other, and the third inclined surface and the fourth inclined surface are disposed to be mirror-symmetrical with each other.

The window further includes a first fixed pole protruding from an inner surface of the window, and the housing further includes a first socket configured to fix the first fixed pole.

The window further includes a second fixed pole protruding from the inner surface of the window and spaced apart from the first fixed pole, and the housing further includes a second socket on which the second fixed pole is disposed.

The electronic device further includes an adhesive layer at least partially disposed on an inner surface of the window and spaced apart from the key area.

The electronic device further includes a switch disposed to correspond to the key area and configured to generate an electrical signal associated with heating or a state of a device.

The electronic device further includes a seal disposed between the switch and the key area and configured to be elastically deformed.

The electronic device further includes a mask pad disposed between the housing and the window and elastically deformable.

The housing further includes a recessed sheet toward an inside of the housing, and the sheet defines a recess on which at least a portion of the window is disposed.

An outer surface of the window and at least a portion of an outer surface of the housing are on a substantially same plane.

The key area includes a design element which is a logo, a character, a symbol, or a shape, or a combination thereof.

The first groove includes a first edge that is perpendicular to an outer surface of the window and a second edge that is perpendicular to the outer surface of the window, and the second groove includes a third edge that includes a shape substantially the same as a shape of the first edge and is disposed on the window and a fourth edge that includes a shape substantially the same as a shape of the second edge and is disposed on the housing.

The first groove includes a first round surface and a second round surface, and the second groove includes a third round surface that includes a shape substantially the same as a shape of the first round surface and is disposed on the window and a fourth round surface that includes a shape substantially the same as a shape of the second round surface and is disposed on the housing.

According to an embodiment, a key area of an electronic device may be distinguished. According to an embodiment, the effects of an aerosol-generating device and system are not limited to the above-mentioned effects, and other unmentioned effects can be clearly understood from the above description by those having ordinary skill in the technical field to which the present disclosure pertains.

### BRIEF DESCRIPTION OF THE DRAWINGS

The foregoing and other aspects, features, and advantages of embodiments in the disclosure will be apparent from the following detailed description with reference to the accompanying drawings.

FIG. 1 is a block diagram of an aerosol-generating device according to an embodiment.

FIG. 2A shows an aerosol-generating device according to an embodiment.

FIG. 2B shows an aerosol-generating device according to an embodiment.

FIG. 3 is a perspective view of an aerosol-generating device according to an embodiment.

FIG. 4 is a plan view of an aerosol-generating device according to an embodiment.

FIG. 5 is an exploded perspective view of an aerosol-generating device according to an embodiment.

FIG. 6 is a cross-sectional view of an aerosol-generating device according to an embodiment.

FIG. 7 is a cross-sectional view of an aerosol-generating device according to an embodiment.

FIG. 8 is a cross-sectional view of an aerosol-generating device according to an embodiment.

FIG. 9 is a cross-sectional view of an aerosol-generating device according to an embodiment.

FIG. 10 is a cross-sectional view of an aerosol-generating device according to an embodiment.

FIG. 11 is a cross-sectional view of an aerosol-generating device according to an embodiment.

### DETAILED DESCRIPTION

Hereinafter, the embodiments disclosed in the present specification will be described in detail with reference to the accompanying drawings. The same or similar elements are denoted by the same reference numerals even though they are depicted in different drawings, and redundant descriptions thereof will be omitted. With regard to the description of the drawings, similar reference numerals may be used to refer to similar or related elements.

In the following description, with respect to constituent elements used in the following description, the suffixes “module” and “unit” are used only in consideration of facilitation of description, and do not have mutually distinguished meanings or functions. As used herein, the suffix “module” or “unit” may include a unit implemented in hardware, software, or firmware, and may be used interchangeably with other terms, for example, “logic,” “logic block,” “part,” or “circuitry.” A “module” or a “unit” may be a single integral component, or a minimum unit or part thereof, adapted to perform one or more functions. For example, the “module” or the “unit” may be implemented in the form of an application-specific integrated circuit (ASIC).

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and spirit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

Embodiments as set forth herein may be implemented as software including one or more instructions that are stored in a storage medium (e.g., a memory 17) that is readable by a machine (e.g., the aerosol-generating device 1). For example, a processor (e.g., the controller 12) of the machine (e.g., the aerosol-generating device 1) may invoke at least one of the one or more instructions stored in the storage medium, and may execute the same. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

In the present disclosure, the directions of the aerosol-generating device 1 may be defined based on the orthogonal coordinate system. In the orthogonal coordinate system, the x-axis direction may be defined as a leftward-rightward direction of the aerosol-generating device 1. The y-axis direction may be defined as a forward-backward direction of the aerosol-generating device 1. The z-axis direction may be defined as an upward-downward direction of the aerosol-generating device 1.

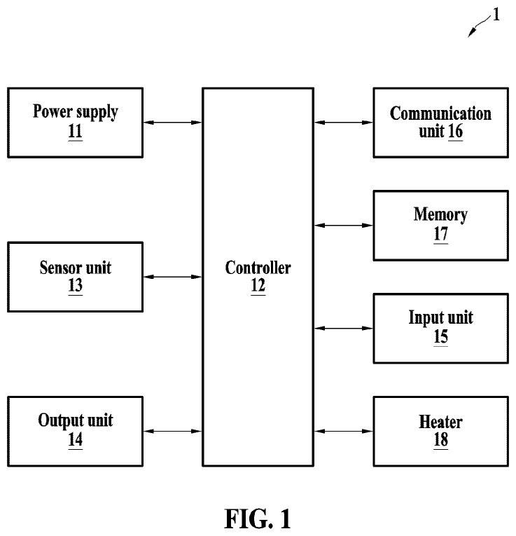

FIG. 1 is a block diagram of an aerosol-generating device according to an embodiment.

According to one embodiment, the aerosol-generating device 1 may include a power supply 11, a controller 12, a sensor unit 13, an output unit 14, an input unit 15, a communication unit 16, a memory 17, and/or a heater 18 and 24. However, the components included in the aerosol-generating device 1 are not limited to those shown in FIG. 1. That is, it will be understood by those skilled in the art related to the present embodiment that some of the components shown in FIG. 1 may be omitted or new components may be further included depending on the design of the aerosol-generating device 1.

According to one embodiment, the sensor unit 13 may detect the state of the aerosol-generating device 1 or the state of the surroundings of the aerosol-generating device 1, and may transmit the detected information to the controller 12. For example, the sensor unit 13 may include a temperature sensor, a puff sensor, an insertion detection sensor, a reuse detection sensor, an overly moist state detection sensor, a cigarette identification sensor, a cartridge detection sensor, a cap detection sensor, and/or a movement detection sensor. Meanwhile, the sensor unit 13 may further include various sensors, such as a liquid residual quantity sensor for detecting the residual quantity of liquid in the cartridge and an immersion sensor for detecting immersion of the aerosol-generating device 1.

According to one embodiment, the temperature sensor may detect a temperature to which the heater 18 and 24 is heated. The aerosol-generating device 1 may include a separate temperature sensor for detecting the temperature of the heater 18 and 24, or the heater 18 and 24 itself may serve as a temperature sensor. In an example, the temperature sensor may be used to measure impedance for the heater 18. The impedance for the heater 18 may correlate with the temperature of the heater 18. The temperature sensor may measure current and/or voltage applied to the heater 18 (or an induction coil). The impedance for the heater 18 may be obtained based on the measured current and/or voltage. The controller 12 may estimate the temperature of the heater 18 based on the obtained impedance.

In an example, the temperature sensor may include a resistance element (e.g., a thermistor), the resistance value of which varies in response to changes in the temperature of the heater 18 and 24. The temperature sensor may output a signal corresponding to the resistance value of the resistance element, and the controller 12 may determine the temperature of the heater 18 and 24 and/or a change in the temperature of the heater 18 and 24 based on the signal corresponding to the resistance value.

In another example, the temperature sensor may include a sensor that detects the resistance value of the heater 18 and 24. The temperature sensor may output a signal corresponding to the resistance value of the heater 18 and 24, and the controller 12 may determine the temperature of the heater 18 and 24 and/or a change in the temperature of the heater 18 and 24 based on the signal corresponding to the resistance value.

According to one embodiment, the temperature sensor may detect the temperature of the power supply 11. The temperature sensor may be disposed adjacent to the power supply 11. For example, the temperature sensor may be attached to one surface of the power supply 11 (e.g., a battery) and/or may be mounted on one surface of a printed circuit board. In an example, the aerosol-generating device 1 may include a power supply protection circuit module (PCM), and the temperature sensor may be disposed adjacent to the power supply 11 together with the power supply protection circuit module.

According to one embodiment, the temperature sensor may be disposed in a housing (not shown) of the aerosol-generating device 1 to detect the internal temperature of the housing (not shown).

According to one embodiment, the puff sensor may detect a user's puff.

In an example, the puff sensor may include a pressure sensor. The pressure sensor may output a signal corresponding to the internal pressure of the aerosol-generating device 1, and the controller 12 may determine the user's puff based on the signal corresponding to the internal pressure. Here, the internal pressure of the aerosol-generating device 1 may correspond to the pressure of an airflow path through which gas flows. The puff sensor may be disposed corresponding to the airflow path through which gas flows in the aerosol-generating device 1.

In another example, the puff sensor may include a temperature sensor. When the user's puff occurs, temperature drop may temporarily occur in the airflow path, a space into which an aerosol-generating article is inserted (hereinafter referred to as an “insertion space”), and the heater 18 and 24. The controller 12 may determine the user's puff based on a signal corresponding to the temperature of the airflow path output from the temperature sensor.

In still another example, the puff sensor may include both a pressure sensor and a temperature sensor. In this case, the temperature sensor may measure temperature used to calibrate the internal pressure measured by the pressure sensor. In one example, the puff sensor may calibrate a signal corresponding to the internal pressure based on the temperature measured by the temperature sensor, and may output the calibrated signal. In another example, the puff sensor may output a signal corresponding to the temperature measured by the temperature sensor and a signal corresponding to the internal pressure measured by the puff sensor. In this case, the controller 12 may receive the signals, and may calibrate the signal corresponding to the internal pressure based on the signal corresponding to the temperature.

In still another example, the puff sensor may include a capacitance sensor. The capacitance sensor may also be called a cap sensor or a capacitive sensor. When the user's puff occurs, a temperature change and/or aerosol flow may occur in the insertion space of the aerosol-generating article, and accordingly, a dielectric constant in the insertion space may change. The controller 12 may determine the user's puff based on a signal corresponding to the dielectric constant in the insertion space output from the capacitance sensor.

The puff sensor is not limited to the examples described above, and may be implemented as various sensors for detecting the user's puff.

According to one embodiment, the insertion detection sensor may detect insertion and/or removal of the aerosol-generating article. The insertion detection sensor may be mounted adjacent to the insertion space. In addition, the insertion detection sensor may include any combination of the examples described above.

In an example, the insertion detection sensor may include a capacitance sensor. The capacitance sensor may include at least one conductor, and the at least one conductor may be disposed adjacent to the insertion space. When the aerosol-generating article is inserted into or removed from the insertion space, capacitance around the conductor may change. The controller 12 may determine insertion and/or removal of the aerosol-generating article based on a signal corresponding to the dielectric constant in the insertion space output from the capacitance sensor.

In another example, the insertion detection sensor may include an inductive sensor. The inductive sensor may include at least one coil, and the at least one coil may be disposed adjacent to the insertion space. If the aerosol-generating article (e.g., a wrapper of the aerosol-generating article) includes a conductor, when the aerosol-generating article is inserted into or removed from the insertion space, a change in magnetic field may occur around the coil through which current flows. The controller 12 may determine insertion and/or removal of the aerosol-generating article including a conductor based on the characteristics of the current output from or detected by the inductive sensor (e.g., frequency of alternating current, a current value, a voltage value, an inductance value, and an impedance value). Alternatively, a susceptor SUS or the like may be included in the aerosol-generating article (e.g., a medium portion of the aerosol-generating article). In this case, a change in magnetic field may also occur around the coil based on insertion or removal of the susceptor or the like into or from the insertion space, and the controller 12 may determine insertion and/or removal of the aerosol-generating article based on the characteristics of the current of the inductive sensor.

The insertion detection sensor is not limited to the examples described above, and may be implemented as various sensors (e.g., a proximity sensor) for detecting insertion and/or removal of the aerosol-generating article. In addition, the insertion detection sensor may include any combination of the examples described above. According to one embodiment, the insertion detection sensor may include a switch or the like for detecting pressing by the aerosol-generating article.

According to one embodiment, the reuse detection sensor may detect whether the aerosol-generating article is being reused. In an example, the reuse detection sensor may be a color sensor for detecting the color of the aerosol-generating article. If the aerosol-generating article is used by the user, a change in the color of a portion of the wrapper may occur due to the generated aerosol or heating. The color sensor may output a signal corresponding to an optical characteristic (e.g., wavelength of light) corresponding to the color of the wrapper based on the light reflected from the wrapper. When a change in the color of a portion of the wrapper is detected, the controller 12 may determine that the aerosol-generating article inserted into the insertion space has already been used.

According to one embodiment, the overly moist state detection sensor may detect whether the aerosol-generating article is in an overly moist state. For example, the overly moist state detection sensor may include a capacitance sensor. The capacitance sensor may include at least one conductor disposed adjacent to the insertion space. The controller 12 may determine whether the aerosol-generating article is in an overly moist state based on the level of a signal corresponding to the dielectric constant or the like output from the capacitance sensor. In an example, the controller 12 may check a level range within which the level of the signal is included based on a look-up table, and may determine the moisture content of the aerosol-generating article based on the checked level range.

According to one embodiment, the cigarette identification sensor may detect whether the aerosol-generating article is authentic and/or may detect the type of the aerosol-generating article.

In an example, the cigarette identification sensor may include an optical sensor for detecting an identification material (or an identification mark) located on the outer surface (e.g., the wrapper) of the aerosol-generating article. The optical sensor may radiate light toward the identification material (or the identification mark) of the aerosol-generating article, and may detect whether the aerosol-generating article is authentic and/or may detect the type of the aerosol-generating article based on the reflected light. For example, the identification material may include a material (i.e., a luminous material) that emits light of a specific wavelength band based on the light radiated thereto. The controller 12 may determine whether the aerosol-generating article is authentic and/or may determine the type of the aerosol-generating article based on the range of the wavelength.

In another example, the cigarette identification sensor may include a capacitance sensor. The dielectric constant in the insertion space may vary depending on the type of the aerosol-generating article inserted into the insertion space. The controller 12 may determine whether the aerosol-generating article is authentic and/or may determine the type of the aerosol-generating article based on a signal corresponding to the dielectric constant or the like in the insertion space output from the capacitance sensor.

In still another example, the cigarette identification sensor may include an inductive sensor. If a conductor is included in the wrapper and/or inner portion (e.g., the medium portion) of the aerosol-generating article inserted into the insertion space, when the aerosol-generating article is inserted into the insertion space, the characteristics of the current detected by the inductive sensor (e.g., frequency of alternating current, a current value, a voltage value, an inductance value, and an impedance value) may vary depending on the type of the aerosol-generating article inserted into the insertion space. The controller 12 may determine whether the inserted aerosol-generating article is authentic and/or may determine the type of the inserted aerosol-generating article based on the characteristics of the current output from or detected by the inductive sensor.

The cigarette identification sensor is not limited to the examples described above, and may be implemented as various sensors for detecting whether the aerosol-generating article is authentic and/or detecting the type of the aerosol-generating article. In addition, the cigarette identification sensor may include any combination of the examples described above.

According to one embodiment, the cartridge detection sensor may detect mounting and/or removal of the cartridge. For example, the cartridge detection sensor may include an inductive sensor, a capacitance sensor, a resistance sensor, a Hall sensor (Hall IC), and/or an optical sensor.

According to one embodiment, the cap detection sensor may detect mounting and/or removal of the cap. For example, the cap detection sensor may include an inductive sensor, a capacitance sensor, a resistance sensor, a contact sensor, a Hall sensor (Hall IC), and/or an optical sensor. The cap may cover at least a portion of the cartridge mounted in or inserted into the aerosol-generating device 1 or may cover at least a portion of the housing of the aerosol-generating device 1. When the cap is mounted in or removed from the housing, the cap detection sensor may output a signal corresponding to mounting or removal, and the controller 12 may determine mounting or removal of the cap based on the signal corresponding to mounting or removal.

According to one embodiment, the movement detection sensor may detect movement of the aerosol-generating device 1. The movement detection sensor may be implemented as at least one of an acceleration sensor or a gyro sensor.

According to one embodiment, the sensor unit 13 may further include at least one of a humidity sensor, an air pressure sensor, a magnetic sensor, a position sensor (global positioning system (GPS)), or a proximity sensor in addition to the sensors described above. The functions of the sensors can be intuitively deduced by those skilled in the art from the names thereof, and thus detailed descriptions thereof may be omitted.

According to one embodiment, the output unit 14 may output information about the state of the aerosol-generating device 1 to provide the same to the user. The output unit 14 may include, but is not limited to, a display, a haptic unit, and/or a sound output unit. For example, information about the aerosol-generating device 1 may include a charging/discharging state of the power supply 11 of the aerosol-generating device 1, a preheating state of the heater 18 and 24, an insertion/removal state of the aerosol-generating article and/or the cartridge, a mounting/removal state of the cap, or a state in which the use of the aerosol-generating device 1 is restricted (e.g., detection of an abnormal object). The display may visually provide the information about the state of the aerosol-generating device 1 to the user. For example, the display may include a light-emitting diode (LED), a liquid crystal display panel (LCD), and an organic light-emitting diode panel (OLED). If the display includes a touchpad, the display may also be used as the input unit 15. The haptic unit may haptically provide the information about the aerosol-generating device 1 to the user. For example, the haptic unit may include a vibration motor, a piezoelectric element, and an electrical stimulation device. The sound output unit may audibly provide the information about the aerosol-generating device 1 to the user. For example, the sound output unit may convert an electrical signal into an acoustic signal and may output the acoustic signal to the outside.

According to one embodiment, the power supply 11 may supply power used for operation of the aerosol-generating device 1. The power supply 11 may include one or more batteries. The power supply 11 may supply power so that the heater 18 and 24 is heated. In addition, the power supply 11 may supply power necessary for operation of the other components included in the aerosol-generating device 1, such as the controller 12, the sensor unit 13, the output unit 14, the input unit 15, the communication unit 16, and the memory 17. The power supply 11 may be a rechargeable battery or a disposable battery. For example, the power supply 11 may be a lithium polymer (LiPoly) battery without being limited thereto. The power supply 11 may be a replaceable (separation-type) battery (hereinafter referred to as a “removable battery”). The removable battery may be mounted in a battery accommodation portion provided in the aerosol-generating device 1 or may be removed from the battery accommodation portion. The removable battery may be charged in a wired and/or wireless manner.

According to one embodiment, the heater 18 and 24 may receive power from the power supply 11 to heat the aerosol-generating article (e.g., a cigarette) and/or a medium and/or an aerosol-generating substance in the cartridge. The aerosol-generating device 1 may include a heater 18 for heating the aerosol-generating article and/or a cartridge heater 24 for heating the cartridge (i.e., a solid and/or liquid medium).

According to one embodiment, the heater 18 and 24 may be an electro-resistive heater. For example, the electro-resistive heater may include an electrically resistive material such as a metal or a metal alloy including titanium, zirconium, tantalum, platinum, nickel, cobalt, chromium, hafnium, niobium, molybdenum, tungsten, tin, gallium, manganese, iron, copper, stainless steel, and nichrome. The electro-resistive heater may be implemented as a metal wire, a metal plate having an electrically conductive track disposed thereon, or a ceramic heating element.

According to one embodiment, the heater 18 and 24 may be an induction heater. For example, the induction heater may include a susceptor that generates heat through a magnetic field. A magnetic field may be generated by an induction coil by alternating current flowing through the induction coil. The magnetic field may pass through the heater, and an eddy current may be generated in the susceptor. The susceptor may be heated based on generation of the eddy current. According to one embodiment, the susceptor may be included in the inner portion (e.g., the medium portion) of the aerosol-generating article. In this case, the susceptor included in the inner portion of the aerosol-generating article may also be heated by the induction coil.

The heater 18 and 24 is not limited to the examples described above, and may include or be replaced with various heating methods, structures, and components for heating the aerosol-generating article and/or the cartridge.

According to one embodiment, the input unit 15 may receive information input from the user. For example, the input unit 15 may include a touch panel, a button, a keypad, a dome switch, a jog wheel, and a jog switch.

According to one embodiment, the memory 17 may be hardware storing various pieces of data processed in the aerosol-generating device 1. The memory 17 may store data processed and to be processed by the controller 12. For example, the memory 17 may include at least one type of storage medium among a flash memory type memory, a hard disk type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. For example, the memory 17 may store data on an operation time of the aerosol-generating device 1, the maximum number of puffs, the current number of puffs, at least one temperature profile, and the user's smoking pattern.

According to one embodiment, the communication unit 16 may include at least one component for communication with other electronic devices (e.g., a portable electronic device). For example, the communication unit 16 may include a Bluetooth communication unit, a Bluetooth low energy (BLE) communication unit, a near-field communication unit, a wireless local area network (WLAN) communication unit, a Zigbee communication unit, an infrared data association (IrDA) communication unit, a Wi-Fi direct (WFD) communication unit, an ultra-wideband (UWB) communication unit, an Ant+ communication unit, a cellular network communication unit, an Internet communication unit, and a computer network (e.g., LAN or WAN) communication unit.

According to one embodiment, the controller 12 may control the overall operation of the aerosol-generating device 1. For example, the controller 12 may include at least one processor. The controller 12 may be implemented as an array of a plurality of logic gates or may be implemented as a combination of a general-purpose microcontroller unit (MCU) (or a microprocessor) and a memory in which a program executable by the MCU is stored. It will be understood by those skilled in the art that the controller may also be implemented as other forms of hardware.

According to one embodiment, the controller 12 may control the supply of power from the power supply 11 to the heater 18 and 24 to control the temperature of the heater 18 and 24. The controller 12 may control the temperature of the heater 18 and 24 and/or power supplied to the heater 18 and 24 based on the temperature of the heater 18 and 24 detected by the temperature sensor (e.g., the sensor unit 13). The controller 12 may control the temperature of the heater 18 and 24 and/or power supplied to the heater 18 and 24 based on the temperature profile and/or the power profile stored in the memory 17.

According to one embodiment, the controller 12 may control a power conversion circuit (not shown) electrically connected to the heater 18 and 24 and the power supply 11 to control power (e.g., voltage and/or current) supplied to the heater 18 and 24. For example, the power conversion circuit may include a DC/DC converter (e.g., a buck converter, a buck-boost converter, a boost converter, or a Zener diode) that converts power to be supplied to the heater 18 and 24 and a DC/AC converter (e.g., an inverter) that converts power to be supplied to the induction coil (not shown). The DC/AC converter may be implemented as a full-bridge circuit or a half-bridge circuit including a plurality of switching elements. For example, the power conversion circuit may include at least one switching element, such as a bipolar junction transistor (BJT) or a field effect transistor (FET).

According to one embodiment, the controller 12 may control the frequency and/or duty ratio of a current pulse input to at least one switching element of the power conversion circuit (not shown) to control the current and/or the voltage supplied to the heater 18 and 24. The duty ratio for the on/off operation of the switching element may correspond to a ratio of the voltage output from the power conversion circuit to the voltage output from the power supply 11.

According to one embodiment, the controller 12 may control power supplied to the heater 18 and 24 using at least one of a pulse width modulation (PWM) scheme or a proportional-integral-differential (PID) scheme. For example, the controller 12 may perform control using the PWM scheme such that a current pulse having a predetermined frequency and a predetermined duty ratio is supplied to the heater 18 and 24. The controller 12 may control the frequency and duty ratio of the current pulse to control power supplied to the heater 18 and 24. For example, the controller 12 may determine, based on the temperature profile, a target temperature to be controlled. The controller 12 may control power supplied to the heater 18 and 24 using the PID scheme, which is a feedback control scheme using a difference value between the temperature of the heater 18 and the target temperature, a value obtained by integrating the difference value with respect to time, and a value obtained by differentiating the difference value with respect to time.

According to one embodiment, the controller 12 may determine, based on the power profile, target power to be controlled. The controller 12 may control power supplied to the heater 18 and 24 so as to correspond to the preset target power over time.

According to one embodiment, the controller 12 may detect power supplied to the heater 18 and 24 to determine the user's puff. In more detail, the controller 12 may control power supplied to the heater 18 and 24 using the proportional-integral-differential (PID) scheme. When the user's puff occurs, temperature drop may temporarily occur in a space into which the aerosol-generating article is inserted (hereinafter referred to as an insertion space) and the heater 18 and 24. Accordingly, the power (or the current) supplied to the heater 18 and 24 may change during control of the power using the PID scheme. The controller 12 may determine the user's puff based on the change in the power controlled.

According to one embodiment, the controller 12 may prevent the heater 18 and 24 from overheating. For example, the controller 12 may control, based on the temperature of the heater 18 and 24 exceeding a preset limit temperature, operation of the power conversion circuit such that the amount of power supplied to the heater 18 and 24 is reduced or the supply of power to the heater 18 and 24 is interrupted.

According to one embodiment, the controller 12 may control charging/discharging of the power supply 11. For example, the controller 12 may check the temperature of the power supply 11 using the temperature sensor (e.g., the sensor unit 13). If the temperature of the power supply 11 is equal to or higher than a first limit temperature, the controller 12 may interrupt charging of the power supply 11. If the temperature of the power supply 11 is equal to or higher than a second limit temperature, the controller 12 may interrupt use of the power stored in the power supply 11 (e.g., discharging). The controller 12 may calculate the remaining amount of the power stored in the power supply 11. For example, the controller 12 may calculate the remaining capacity of the power supply 11 based on a voltage and/or current detection value of the power supply 11.

According to one embodiment, the controller 12 may control the supply of power to the heater 18 and 24 based on a result of the detection by the sensor unit 13.

According to one embodiment, the controller 12 may control the supply of power to the heater 18 and 24 based on insertion and/or removal of the aerosol-generating article into and/or from the insertion space. For example, upon determining that the aerosol-generating article has been inserted into the insertion space using the insertion detection sensor (e.g., the sensor unit 13), the controller 12 may perform control such that power is supplied to the heater 18 and 24. Upon determining that the aerosol-generating article has been removed from the insertion space using the insertion detection sensor (e.g., the sensor unit 13), the controller 12 may interrupt the supply of power to the heater 18 and 24. The controller 12 may determine that the aerosol-generating article has been removed from the insertion space when the temperature of the heater 18 and 24 is equal to or higher than a limit temperature or when the temperature change slope of the heater 18 and 24 is equal to or greater than a preset slope.

According to one embodiment, the controller 12 may control, based on the state of the aerosol-generating article, a power supply time and/or the amount of power supplied to the heater 18 and 24. For example, upon determining that the aerosol-generating article is in an overly moist state using the overly moist state detection sensor (e.g., the sensor unit 13), the controller 12 may increase a time during which power is supplied to the heater 18 and 24 (e.g., a preheating time).

According to one embodiment, the controller 12 may control the supply of power to the heater 18 and 24 based on whether the aerosol-generating article is being reused. For example, upon determining that the aerosol-generating article has already been used, the controller 12 may interrupt the supply of power to the heater 18 and 24.

According to one embodiment, the controller 12 may control the supply of power to the heater 18 and 24 based on whether the cartridge has been coupled and/or removed. For example, upon determining that the cartridge has been removed using the cartridge detection sensor (e.g., the sensor unit 13), the controller 12 may interrupt the supply of power to the heater 18 or 24 or may perform control such that power is not supplied to the heater 18 and 24.

According to one embodiment, the controller 12 may control the supply of power to the heater 18 and 24 based on whether the aerosol-generating substance in the cartridge has been exhausted. For example, upon determining that the temperature of the heater 18 and 24 exceeds a limit temperature during preheating of the heater 18 and 24 (i.e., in the preheating section), the controller 12 may determine that the aerosol-generating substance in the cartridge has been exhausted. Upon determining that the aerosol-generating substance in the cartridge has been exhausted, the controller 12 may interrupt the supply of power to the heater 18 and 24.

According to one embodiment, the controller 12 may control the supply of power to the heater 18 and 24 based on whether use of the cartridge is possible. For example, upon determining, based on data stored in the memory 17, that the current number of puffs is equal to or greater than the maximum number of puffs set for the cartridge, the controller 12 may determine that use of the cartridge is impossible. Alternatively, when a total time period during which the heater 18 and 24 is heated is equal to or longer than a preset maximum time period or when the total amount of power supplied to the heater 18 and 24 is equal to or greater than a preset maximum amount of power, the controller 12 may determine that use of the cartridge is impossible. In this case, the controller 12 may interrupt the supply of power to the heater 18 or 24 or may perform control such that power is not supplied to the heater 18 and 24.

According to one embodiment, the controller 12 may control the supply of power to the heater 18 and 24 based on the user's puff. For example, the controller 12 may determine whether a puff occurs and/or the intensity of a puff using the puff sensor (e.g., the sensor unit 13). When the number of puffs reaches a preset maximum number of puffs and/or when no puff is detected for a preset time period or longer, the controller 12 may interrupt the supply of power to the heater 18 and 24. When a puff is detected, the controller 12 may control the supply of power to the heater 18 and 24.

According to one embodiment, the controller 12 may control the supply of power to the heater 18 and 24 based on whether the aerosol-generating article (or the cartridge) is authentic and/or the type of the aerosol-generating article (or the cartridge). For example, the controller 12 may determine whether the aerosol-generating article is authentic and/or may determine the type of the aerosol-generating article using the cigarette identification sensor (e.g., the sensor unit 13). In an example, upon determining that the aerosol-generating article (or the cartridge) is inauthentic, the controller 12 may interrupt the supply of power to the heater 18 and 24. Upon determining that the aerosol-generating article (or the cartridge) is authentic, the controller 12 may control (e.g., commence) the supply of power to the heater 18 and 24. In another example, the controller 12 may control the supply of power to the heater 18 and 24 differently depending on the type of the aerosol-generating article (or the cartridge). In more detail, upon determining that the aerosol-generating article (or the cartridge) is a first aerosol-generating article (or a first cartridge), the controller 12 may control the temperature of the heater 18 and 24 and/or power based on a first temperature profile (or a first power profile), and upon determining that the aerosol-generating article (or the cartridge) is a second aerosol-generating article (or a second cartridge), the controller 12 may control the temperature of the heater 18 and 24 and/or power based on a second temperature profile (or a second power profile).

According to one embodiment, the controller 12 may control the output unit 14 based on a result of detection by the sensor unit 13. For example, when the number of puffs counted using the puff sensor (e.g., the sensor unit 13) reaches a preset number, the controller 12 may control the output unit 14 to visually, haptically, and/or audibly provide information that operation of the aerosol-generating device 1 will end soon. For example, the controller 12 may control the output unit 14 to visually, haptically, and/or audibly provide information about the temperature of the heater 18 and 24.

According to one embodiment, based on occurrence of a predetermined event, the controller 12 may store a history of the corresponding event in the memory 17 and may update the history. For example, the event may include events performed in the aerosol-generating device 1, such as detection of insertion of the aerosol-generating article, commencement of heating of the aerosol-generating article, detection of puff, termination of puff, detection of overheating of the heater 18 and 24, detection of application of overvoltage to the heater 18 and 24, termination of heating of the aerosol-generating article, on/off operation of the aerosol-generating device 1, commencement of charging of the power supply 11, detection of overcharging of the power supply 11, and termination of charging of the power supply 11. For example, the history of the event may include the occurrence date and time of the event and log data corresponding to the event. For example, when the predetermined event is detection of insertion of the aerosol-generating article, the log data corresponding to the event may include data on a value detected by the insertion detection sensor (e.g., the sensor unit 13). For example, when the predetermined event is detection of overheating of the heater 18 and 24, the log data corresponding to the event may include data on the temperature of the heater 18 and 24, the voltage applied to the heater 18 and 24, and the current flowing through the heater 18 and 24.

According to one embodiment, the controller 12 may control the communication unit 16 to form a communication link with an external device such as a user's mobile terminal.

According to one embodiment, upon receiving data on authentication from an external device via the communication link, the controller 12 may release restriction on use of at least one function (e.g., a heating function) of the aerosol-generating device 1. For example, the data on authentication may include the user's birthday, an identification number uniquely identifying the user, and whether authentication is completed by the user.

According to one embodiment, the controller 12 may transmit data on the state of the aerosol-generating device 1 (e.g., remaining capacity of the power supply 11 and operation mode) to the external device via the communication link. The transmitted data may be output through a display or the like of the external device.

According to one embodiment, upon receiving a request to search for the location of the aerosol-generating device 1 from the external device via the communication link, the controller 12 may control the output unit 14 to perform an operation corresponding to location search. For example, the controller 12 may perform control such that the haptic unit generates vibration or the display outputs objects corresponding to location search and termination of search.

According to one embodiment, upon receiving firmware data from the external device via the communication link, the controller 12 may perform firmware update.

According to one embodiment, the controller 12 may transmit data on a value detected by the at least one sensor unit 13 to an external server (not shown) via the communication link, and may receive, from the server, and store a learning model generated by learning the detected value through machine learning such as deep learning. The controller 12 may perform the operation of determining the user's puff pattern and the operation of generating the temperature profile using the learning model received from the server.

Although not shown in FIG. 1, the aerosol-generating device 1 may further include a power supply protection circuit. The power supply protection circuit may include at least one switching element, and may block an electric path to the power supply 11 in response to overcharging and/or overdischarging of the power supply 11. The aerosol-generating device 1 may further include a connection interface such as a universal serial bus (USB) interface, and may be connected to other external devices through the connection interface to transmit and receive information or charge the power supply 11.

The aerosol-generating article mentioned in the present disclosure may include at least one aerosol-generating rod (e.g., a medium portion) and at least one filter rod. The heater 18 may be disposed to correspond to the at least one aerosol-generating rod, and may be designed differently depending on the arrangement order and/or positions of the aerosol-generating rod and the filter rod. The aerosol-generating rod may contain at least one of nicotine, an aerosol-generating substance, and an additive. For example, the aerosol-generating substance may include glycerin (e.g., vegetable glycerin (VG)) and/or propylene glycol (PG) and may also include various other substances. For example, the additive may include a flavoring agent and/or an organic acid and may also include various other substances. For example, the aerosol-generating rod may include an aerosol-generating substrate (e.g., a sheet) impregnated with a liquid non-tobacco substance (e.g., an aerosol-generating substance and/or nicotine) and/or may contain a solid tobacco substance (e.g., leaf tobacco and reconstituted tobacco). The tobacco substance may be contained in the aerosol-generating rod in various forms, such as shredded tobacco, granules, and powder. According to one embodiment, the additive of the aerosol-generating rod may include an alkaline substance. Based on the alkaline substance, nicotine contained in the tobacco substance in the aerosol-generating rod may have an alkaline pH (e.g., pH 7.0 or higher). In this case, freebase nicotine may be released from the aerosol-generating rod even at a low temperature. According to one embodiment, the aerosol-generating rod may include two or more aerosol-generating rods, each of which may contain a tobacco substance and/or a non-tobacco substance. Meanwhile, although not shown, the at least one aerosol-generating rod and the at least one filter rod may individually and/or integrally be wrapped by at least one wrapper. In the present disclosure, the aerosol-generating article may be referred to as a stick.

The cartridge mentioned in the present disclosure may contain an aerosol-generating substance having any one state among a liquid state, a solid state, a gaseous state, and a gel state. The aerosol-generating substance may include a liquid composition. For example, the liquid composition may be a liquid containing a tobacco-containing substance including a volatile tobacco flavor component or may be a liquid containing a non-tobacco substance. Meanwhile, the cartridge may include a storage part that contains the aerosol-generating substance and/or a liquid delivery part that is impregnated with (contains) the aerosol-generating substance. For example, the liquid delivery part may include a wick formed of, e.g., cotton fiber, ceramic fiber, glass fiber, or porous ceramic. The cartridge heater 24 may be included in the cartridge in a coil-shaped structure surrounding (or wound around) the liquid delivery part or a structure contacting one side of the liquid delivery part. Alternatively, the cartridge heater 24 may be included in the aerosol-generating device 1, which is removable from the cartridge.

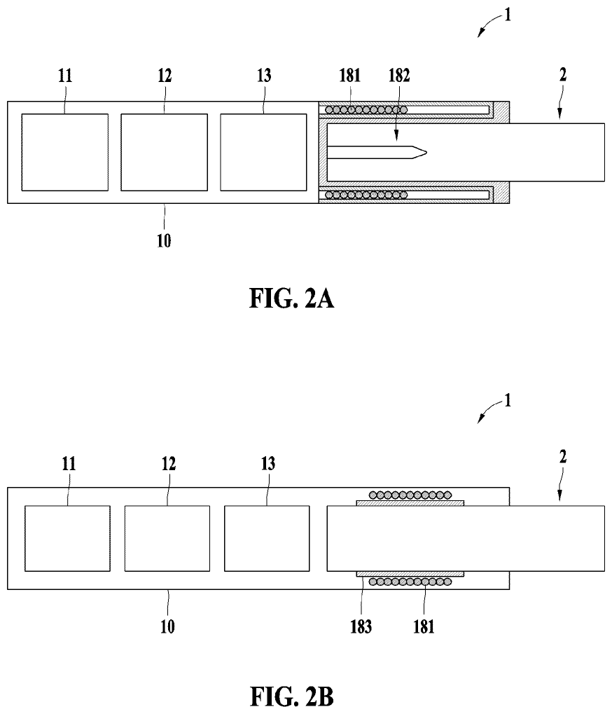

FIG. 2A shows an aerosol-generating device 1 according to an embodiment. FIG. 2B shows an aerosol-generating device 1 according to an embodiment.

According to one embodiment, the aerosol-generating device 1 may include a housing 10, a power supply 11, a controller 12, a sensor unit 13, and/or a heater 182 and 183 (e.g., the heater 18 in FIG. 1). However, it will be understood by those skilled in the art related to the present embodiment that the components included in the aerosol-generating device 1 are not limited to those shown in FIG. 2A or FIG. 2B and that some of the components may be omitted or new components may be further included. The aerosol-generating device 1 shown in FIG. 2A may be referred to as an “internal heating-type” aerosol-generating device that heats the inner side of an aerosol-generating article 2. The aerosol-generating device 1 shown in FIG. 2B may be referred to as an “external heating-type” aerosol-generating device that heats the outer side of the aerosol-generating article 2. In the drawings below, a description of configurations identical to those shown in FIG. 1 will be omitted.

According to one embodiment, the housing 10 may provide a space that is open upwardly to allow the aerosol-generating article 2 to be inserted thereinto. In the present disclosure, the space that is open upwardly may be referred to as an insertion space. The insertion space may be formed so as to be depressed in the housing 10 to a predetermined depth so that at least a portion of the aerosol-generating article 2 may be inserted thereinto. The depth of the insertion space may be equal to or greater than the length of a region of the aerosol-generating article 2 in which an aerosol-generating substance and/or a medium is contained. The lower end of the aerosol-generating article 2 may be inserted into the housing 10, and the upper end of the aerosol-generating article 2 may protrude outside the housing 10. A user may inhale an aerosol while holding the externally exposed upper end of the aerosol-generating article 2 in the mouth.

According to one embodiment, the heater 182 and 183 may heat the aerosol-generating article 2.

Referring to FIG. 2A, the heater 182 may be an internal heating-type heater.

According to one embodiment, the internal heating-type heater may be elongated upwardly in the space into which the aerosol-generating article 2 is inserted (i.e., the insertion space). For example, as shown in the drawings, the internal heating-type heater may include a rod-shaped or needle-shaped heating element. Alternatively, the internal heating-type heater may include various other heating elements, such as a tubular heating element or a plate-shaped heating element. The internal heating-type heater may be inserted through the lower portion of the aerosol-generating article 2.

According to one embodiment, the internal heating-type heater may include an electro-resistive heater and/or an induction heater.

For example, the electro-resistive heater may include an electro-resistive material, which is provided on the inner side (e.g., in the cavity or on the inner surface) or outer side (e.g., on the outer surface) thereof, and may generate heat as current flows through the electro-resistive material. In this case, the electro-resistive heater may be electrically connected to the power supply 11, and may directly generate heat using current received from the power supply 11. Meanwhile, an induction coil 181 may be omitted.

For example, in the case of an induction heater, the aerosol-generating device 1 may include an induction coil 181 surrounding at least a portion of the internal heating-type heater (e.g., disposed outside the heater so as to correspond to the length of at least a portion of the heater). In this case, a magnetic flux concentrator may be further provided outside the induction coil 181 in order to increase efficiency of induction heating. The induction heater may include a susceptor, and may generate heat based on a magnetic field generated by the induction coil 181. According to one embodiment, the induction heater (e.g., the susceptor) (or a heater module including the same) may be disposed to be removable from the housing 10.

According to one embodiment, the heater 182 may be a multi-heater. The multi-heater may include a first heater and a second heater, and may be inserted into the aerosol-generating article 2. The first heater and the second heater may be disposed side by side in the longitudinal direction. The first heater and the second heater may operate as an electro-resistive heater and/or an induction heater, and may be heated sequentially or simultaneously. In this case, the first heater and the second heater may be disposed at positions corresponding to the positions of two or more aerosol-generating rods in the longitudinal direction, respectively. Alternatively, the first heater and the second heater may be disposed at positions corresponding to the positions of a first portion and a second portion of one aerosol-generating rod in the longitudinal direction, respectively. Meanwhile, if the heater 182 is an induction heater, the aerosol-generating device 1 may include a first induction coil and a second induction coil, and the first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 182 in the longitudinal direction, respectively. In addition, three or more heaters and/or three or more induction coils may be included.

According to one embodiment, the susceptor may be disposed on (or included in) the inner side (e.g., the medium portion) of the aerosol-generating article 2. The susceptor included inside the aerosol-generating article 2 may be implemented to be heated based on a magnetic field generated by the induction coil 181.

Referring to FIG. 2B, the heater 183 may be an external heating-type heater.

According to one embodiment, the external heating-type heater may be elongated upwardly around the space into which the aerosol-generating article 2 is inserted (i.e., the insertion space). For example, the external heating-type heater may be disposed so as to surround at least a portion of the insertion space. In an example, the external heating-type heater may include a tube shape (e.g., a cylindrical shape) with a cavity formed therein. The external heating-type heater may alternatively include a shape including a cavity formed therein and surrounding the cavity. In this case, the external heating-type heater may be supported by a polyimide film. The heater supported by this film may be referred to as a film heater. The external heating-type heater may be disposed so as to surround at least a portion of the insertion space. The external heating-type heater may heat the outer side of the aerosol-generating article 2 inserted into the cavity.

According to one embodiment, the external heating-type heater may include an electro-resistive heater and/or an induction heater, and a description of configurations identical to those shown in FIG. 2A will be omitted. Meanwhile, in the case of an induction heater, the aerosol-generating device 1 may include an external heating-type heater implemented as a tubular susceptor and may include an induction coil 181 surrounding at least a portion of the external heating-type heater (e.g., disposed outside the heater so as to correspond to the length of at least a portion of the heater). In addition, the induction coil 181 may include a fan coil. Meanwhile, if the external heating-type heater is an electro-resistive heater, heat may be generated through current flow through the tubular electro-resistive heater (e.g., the film heater), and thus a separate induction coil 181 may be omitted. Meanwhile, a thermally insulating material may be disposed outside the external heating-type heater. Accordingly, the amount of heat emitted from the heater 183 in the radially outward direction and released outside the housing 10 may be reduced.

According to one embodiment, the heater 183 may be a multi-heater, and the first heater and the second heater may be disposed side by side in the longitudinal direction so as to surround at least a portion of the insertion space. The first heater and the second heater may operate as an electro-resistive heater and/or an induction heater, and may be heated sequentially or simultaneously. Meanwhile, if the heater 183 is an induction heater, the aerosol-generating device 1 may include a first induction coil and a second induction coil. The first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 183 in the longitudinal direction, respectively.

Unlike the configuration shown in FIG. 2A or FIG. 2B, both the heater 182 in FIG. 2A and the heater 183 in FIG. 2B may be included in the aerosol-generating device 1. In this case, the heater 182 may heat the inner side of the aerosol-generating article 2, and the heater 183 may heat the outer side of the aerosol-generating article 2.

According to one embodiment, the aerosol-generating device 1 may be provided with an airflow channel through which air flows. For example, the housing 10 may include a structure (e.g., a hole) through which outside air may be introduced into the housing 10. The air introduced into the housing 10 may be introduced into the aerosol-generating article 2 through the lower end (i.e., upstream side) of the aerosol-generating article 2. An aerosol generated based on heating of the aerosol-generating article 2 may be inhaled into the user's oral cavity together with the introduced air through the upper end (i.e., downstream side) of the aerosol-generating article 2.

As used herein, the terms “substantially”, “approximately”, “generally”, and “about” in reference to a given parameter, property, or condition may include a degree that one of ordinary skill in the art would understand that the given parameter, property, or condition is met with a small degree of variance, such as within acceptable manufacturing tolerances. For example, a parameter that is substantially met may be at least 90% met, at least 95% met, or at least 99% met.

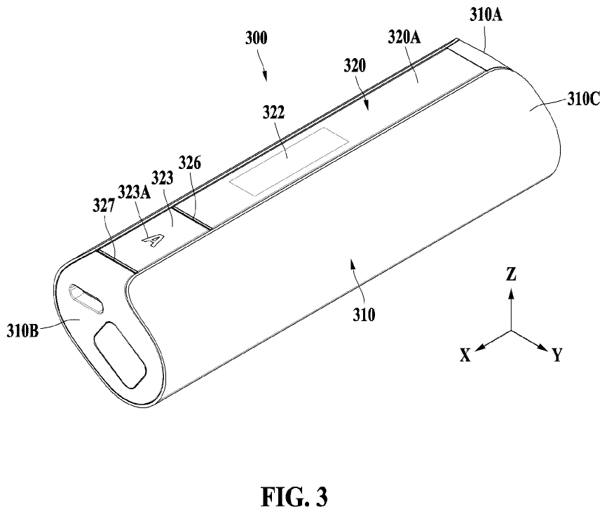

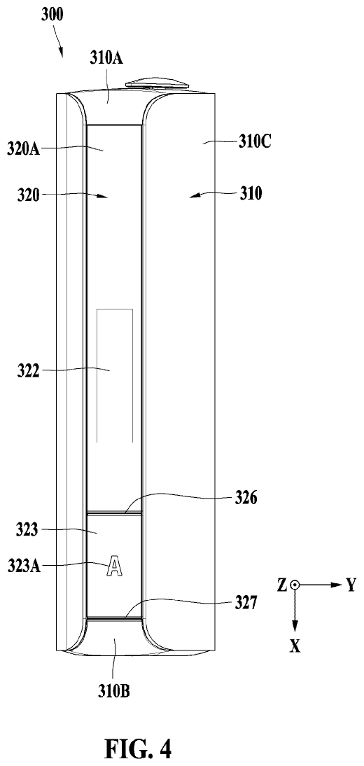

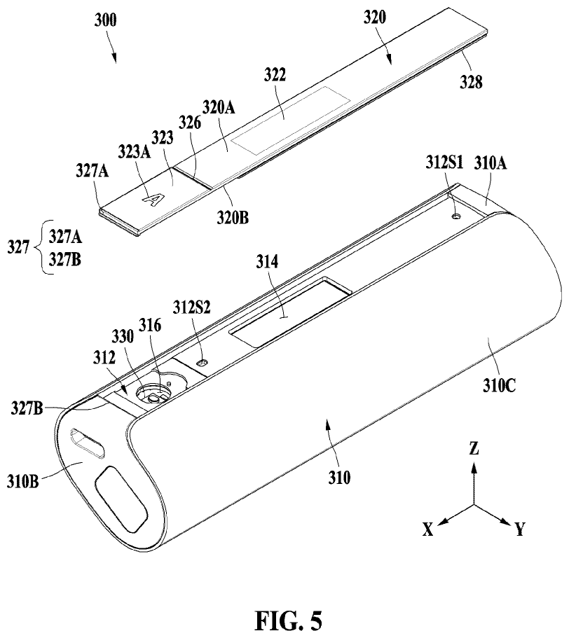

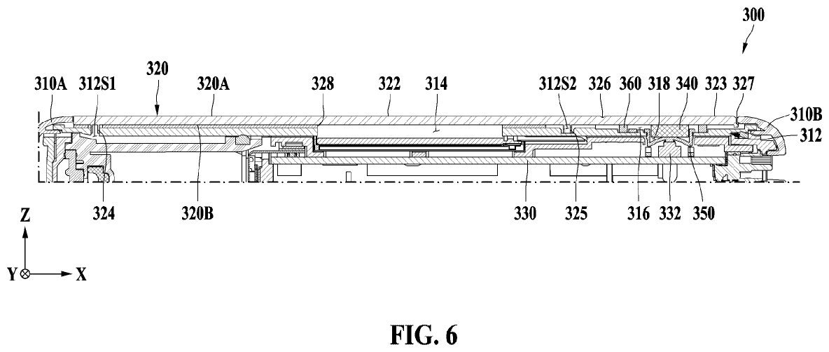

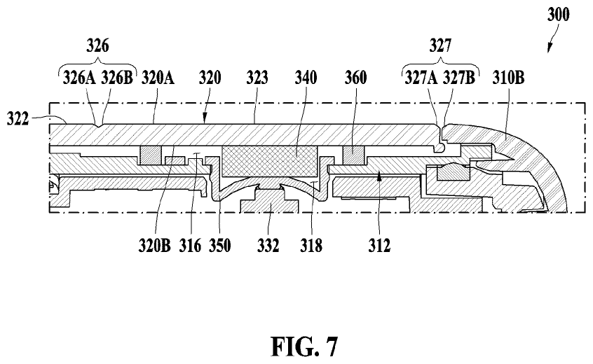

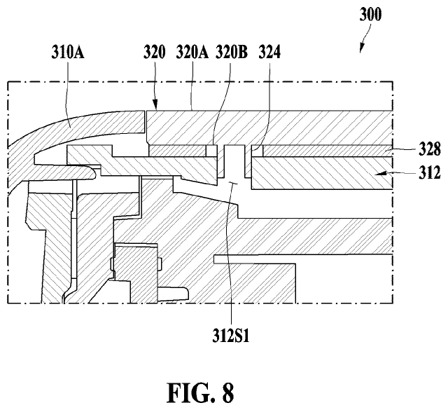

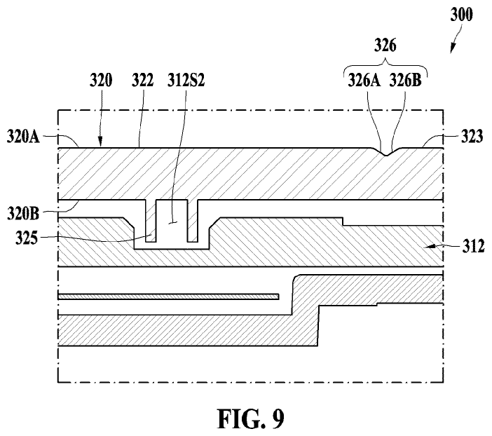

FIG. 3 is a perspective view of an aerosol-generating device according to an embodiment. FIG. 4 is a plan view of an aerosol-generating device according to an embodiment. FIG. 5 is an exploded perspective view of an aerosol-generating device according to an embodiment. FIG. 6 is a cross-sectional view of an aerosol-generating device according to an embodiment. FIG. 7 is a cross-sectional view of an aerosol-generating device according to an embodiment. FIG. 8 is a cross-sectional view of an aerosol-generating device according to an embodiment. FIG. 9 is a cross-sectional view of an aerosol-generating device according to an embodiment.

Referring to FIGS. 3 to 9, a key area 323 of an electronic device 300 (e.g., the aerosol-generating device 1 of FIGS. 1, 2A, and/or 2B) may be distinguished. A first groove 326 and a second groove 327 may be disposed in the key area 323 and/or a housing 310 to visually display a position of the key area 323 and/or aesthetically exhibit a window 320 to a user of the electronic device 300. The user may visually distinguish the key area 323 by light reflected by the first groove 326 and/or the second groove 327.

The electronic device 300 may include the housing 310. The housing 310 may be configured to accommodate at least one component (e.g., a printed circuit board (PCB) 330) related to the operation of the electronic device 300 (e.g., the aerosol-generating device 1 of FIGS. 1, 2A, and/or 2B).

The housing 310 may include a first housing surface 310A (e.g., a top surface or a surface in the −X direction), a second housing surface 310B (e.g., a bottom surface or a surface in the +X direction) that is opposite to the first housing surface 310A, and a housing side surface 310C between the first housing surface 310A and the second housing surface 310B. The housing side surface 310C may be formed as a single surface or a plurality of surfaces.

The housing 310 may include a sheet 312. The sheet 312 may be a recessed portion from the outer surface of the housing 310 toward the inside of the housing 310. At least a portion of the window 320 may be disposed on the sheet 312. The sheet 312 may include a first recess 314 on which a display is disposed and which is disposed below a display area 322. The sheet 312 may include a second recess 316 disposed below the key area 323. The sheet 312 may partially extend in the longitudinal direction (e.g., the X-axis direction) of the housing 310. The sheet 312 may include an opening 318 that penetrates the sheet 312. The opening 318 may be disposed on the second recess 316.

The electronic device 300 may include the window 320. The window 320 may include a first window surface 320A (e.g., an outer surface) and a second window surface 320B (e.g., an inner surface) that is opposite to the first window surface 320A. The window 320 may include a glass material.

The window 320 may include the display area 322. The display area 322 may be a portion in which information about a state of the electronic device 300 is shown to the user. The electronic device 300 may include a display (e.g., the output unit 14 of FIG. 1 or a display) disposed below (e.g., the first recess 314) the display area 322.

The window 320 may include the key area 323 that guides the user to perform a press action. The key area 323 may include a design element 323A. For example, the design element 323A may include at least one of a logo, a symbol, or a shape, or a combination thereof.

The window 320 may include a first fixed pole 324 that protrudes from the second window surface 320B. The first fixed pole 324 may be disposed in the display area 322. The housing 310 may include a first socket 312S1 configured to fix the first fixed pole 324. For example, the thickness (e.g., the size in the X-axis direction) of the first fixed pole 324 may be substantially the same as the width (e.g., the size in the X-axis direction) of the first socket 312S1, and the first fixed pole 324 may be fitted into the first socket 312S1. Although FIG. 8 illustrates that the first socket 312S1 is a hole that penetrates the sheet 312, the example is not limited thereto, and the first socket 312S1 may not penetrate the sheet 312.

The first socket 312S1 may be disposed on a portion of the sheet 312 disposed below the display area 322 of the sheet 312. The first socket 312S1 may correspond to the position of the first fixed pole 324. The first fixed pole 324 and the first socket 312S1 on the side of the display area 322 may fix the display area 322 when the user presses the key area 323.

The window 320 may include a second fixed pole 325 that protrudes from the second window surface 320B. The second fixed pole 325 may be disposed in the display area 322. The housing 310 may include a second socket 312S2 on which the second fixed pole 325 is disposed. For example, the thickness (e.g., the size in the X-axis direction) of the second fixed pole 325 may be less than the width (e.g., the size in the X-axis direction) of the second socket 312S2, and the second fixed pole 325 may be disposed inside the second socket 312S2. Although FIG. 8 illustrates that the second socket 312S2 is a recess that does not penetrate the sheet 312, the example is not limited thereto, and the second socket 312S2 may penetrate the sheet 312.

The second socket 312S2 may be disposed on a portion of the sheet 312 disposed below the display area 322 of the sheet 312. The second socket 312S2 may correspond to the position of the second fixed pole 325. A distance between the second fixed pole 325 and the key area 323 may be less than a distance between the first fixed pole 324 and the key area 323. Since the second fixed pole 325 disposed close to the key area 323 is not fixed to the second socket 312S2, when the user presses the key area 323, the key area 323 may press a switch 332 as the key area 323 moves while maintaining the axis aligned.

The electronic device 300 may include the first groove 326 disposed on the window 320. The first groove 326 may be disposed between the display area 322 and the key area 323. The first groove 326 may be disposed in the first window surface 320A. The first groove 326 may be formed in a direction from the first window surface 320A toward the second window surface 320B. The first groove 326 may extend in the width direction (e.g., the Y-axis direction) of the window 320.

The first groove 326 may include a first inclined surface 326A and a second inclined surface 326B. The first inclined surface 326A and the second inclined surface 326B may be connected to each other. Various angles may be formed by the first inclined surface 326A and the second inclined surface 326B from the first window surface 320A toward the second window surface 320B. Depending on the various angles, the first groove 326 may reflect light to the user at various angles. The angle of light reflected by the first groove 326 to the user may be different from the angle of light reflected by the first window surface 320A to the user. The first inclined surface 326A and the second inclined surface 326B may be disposed to be mirror-symmetrical with respect to a surface therebetween.

The electronic device 300 may include the second groove 327 disposed between the key area 323 and the housing 310. A portion of the second groove 327 may be disposed in the first window surface 320A, and the other portion may be disposed in the second housing surface 310B. The second groove 327 may include a shape that is substantially the same as the shape of the first groove 326. For example, the depth and shape of the first groove 326 may be substantially the same as the depth and shape of the second groove 327. The second groove 327 may extend in the width direction (e.g., the Y-axis direction) of the window 320.

The second groove 327 may include a third inclined surface 327A that includes a shape substantially the same as the shape of the first inclined surface 326A and is disposed on the window 320 and a fourth inclined surface 327B that includes a shape substantially the same as the shape of the second inclined surface 326B and is disposed on the housing 310. The third inclined surface 327A and the fourth inclined surface 327B may be connected to each other with a gap between the window 320 and the housing 310. The third inclined surface 327A and the fourth inclined surface 327B may be disposed to be mirror-symmetrical with respect to a surface therebetween. Even if a gap is provided between the window 320 and the housing 310, since the gap is small, the user may perceive that the third inclined surface 327A and the fourth inclined surface 327B are connected to each other and form a single groove. The second groove 327 may reflect light to the user at an angle that is substantially the same as an angle at which the first groove 326 reflects the light to the user. Due to the light reflected by the first groove 326 and the second groove 327 at substantially the same angle, the user may perceive that both end portions of the key area 323 are components separated from the display area 322 and the housing 310, respectively. For example, the user may perceive a portion where the key area 323 is distinguished from the housing 310 and a portion where the key area 323 is distinguished from the display area 322 as similar, and accordingly, the user may perceive that the key area 323 is not a component included in the window 320 together with the display area 322 and is a separate component.

The electronic device 300 may include an adhesive layer 328 (e.g., double-sided tape) at least partially disposed on the second window 320B and spaced apart from the key area 323. The adhesive layer 328 may keep the display area 322 fixed to the housing 310 (e.g., the sheet 312). Even if the user repeatedly presses the key area 323, the first fixed pole 324 and/or the adhesive layer 328 may ensure that the window 320 remains in position.

The electronic device 300 may include the PCB 330. The PCB 330 may be disposed in an internal space of the housing 310. The electronic device 300 may include the switch 332 disposed on the PCB 330. For example, the switch 332 may include a tact switch. For example, the electronic device 300 may be configured to generate an electrical signal associated with heating or a state of the electronic device 300. The switch 332 may correspond to the position of the key area 322.

The electronic device 300 may include a light diffuser 340 configured to diffuse light. The light diffuser 340 may uniformly diffuse light emitted from a light source (not shown) to the key area 323. When the switch 332 is activated, the light emitted from the light source may be diffused to the key area 323 via the light diffuser 340. The light diffuser 340 may have a substantially cylindrical shape. The light diffuser 340 may at least partially pass through the opening 318 and may be disposed on the second recess 316 and/or the internal space of the housing 310. A pressing force applied to the key area 323 may be transferred to the switch 332 via the light diffuser 340 and may trigger the activation of the switch 332. The light diffuser 340 may include a transparent or translucent material. A cross-sectional area (e.g., the XY plane area) of the light diffuser 340 may be substantially the same as or greater than the area of the design element 323A printed on the key area 323.

The electronic device 300 may include a seal 350 disposed between the key area 323 and the switch 332 and configured to be elastically deformed. A cavity portion of the seal 350 may accommodate at least a portion of the light diffuser 340. The seal 350 may be configured to seal the internal space of the housing 310. The seal 350 may be hermetically coupled to the sheet 312. The seal 350 may reduce or prevent moisture from entering the internal space of the housing 310 via the opening 318.

The seal 350 may be elastically deformed. For example, the seal 350 may include rubber. The pressing force applied to the key area 323 may cause elastic deformation of the seal 350 via the light diffuser 340 and may activate the switch 332. The hardness of the seal 350 may be between approximately 30 and approximately 80. The seal 350 may include a transparent or translucent material.

The electronic device 300 may include a mask pad 360. The mask pad 360 may block an optical path from the second recess 316 to the outside except for an optical path leading to the key area 323 from the light source via the light diffuser 340 and the seal 350. The mask pad 360 may be disposed between the key area 323 and the sheet 312. The mask pad 360 may extend along the entire perimeter of the light diffuser 340 and the entire perimeter of the seal 350. The mask pad 360 may have reduced gloss. The mask pad 360 may be elastically deformed. The mask pad 360 may be compressed to approximately 20% to approximately 80% of its initial shape.

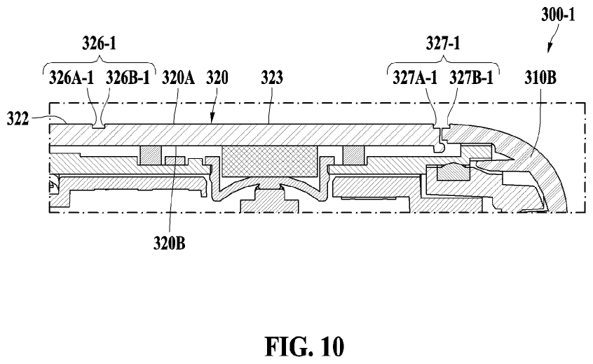

FIG. 10 is a cross-sectional view of an aerosol-generating device according to an embodiment.

Referring to FIG. 10, an electronic device 300-1 (e.g., the aerosol-generating device 1 of FIGS. 1, 2A, and/or 2B or the electronic device 300 of FIGS. 3 to 9) may include a first groove 326-1 and a second groove 327-1. The first groove 326-1 may include a first edge 326A-1 that is substantially perpendicular to the first window surface 320A and a second edge 326B-1 that is substantially perpendicular to the first window surface 320A. The first edge 326A-1 and the second edge 326B-1 that are substantially perpendicular to the first window surface 320A may reflect light to the user at an angle different from the first window surface 320A. The second groove 327-1 may include a third edge 327A-1 that is substantially perpendicular to the first window surface 320A and a fourth edge 327B-1 that is substantially perpendicular to the outer surface of the housing 310. The second groove 327-1 may reflect light to the user at an angle substantially the same as the first groove 326-1.

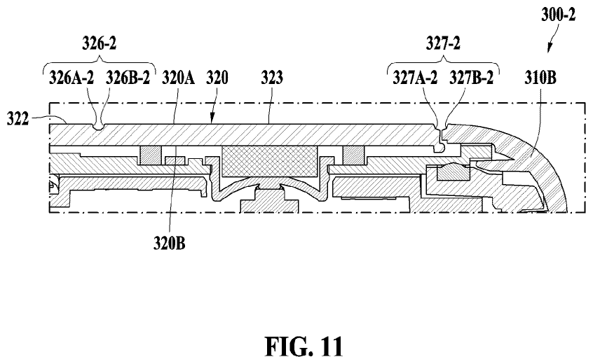

FIG. 11 is a cross-sectional view of an aerosol-generating device according to an embodiment.

Referring to FIG. 11, an electronic device 300-2 (e.g., the aerosol-generating device 1 of FIGS. 1, 2A, and/or 2B, the electronic device 300 of FIGS. 3 to 9, or the electronic device 300-1 of FIG. 10) may include a first groove 326-2 and a second groove 327-2. The first groove 326-2 may include a first round surface 326A-2 and a second round surface 326B-2. The first round surface 326A-2 and the second round surface 326B-2 may reflect light to the user at an angle different from the first window surface 320A. The curvatures of the first round surface 326A-2 and the second round surface 326B-2 may be designed in various manners. Although FIG. 11 illustrates that the first round surface 326A-2 and the second round surface 326B-2 are inwardly concave to the first window surface 320A, the example is not limited thereto, and the first round surface 326A-2 and the second round surface 326B-2 may include convex shapes. The second groove 327-2 may include a third round surface 327A-2 and a fourth round surface 327B-2. The second groove 327-2 may reflect light to the user at an angle substantially the same as the first groove 326-2.

Certain embodiments or other embodiments of the disclosure described above are not mutually exclusive or distinct from each other. Any or all elements of the embodiments of the disclosure described above may be combined with another or combined with each other in configuration or function.

For example, a configuration “A” described in one embodiment of the disclosure and the drawings and a configuration “B” described in another embodiment of the disclosure and the drawings may be combined with each other. Namely, although the combination between the configurations is not directly described, the combination is possible except in the case where it is described that the combination is impossible.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An electronic device comprising:
a housing;
a window comprising a key area and a display area and disposed in a housing;
a first groove disposed between the key area and the display area; and
a second groove disposed between the key area and the housing and comprising a shape that is substantially the same as a shape of the first groove.

2. The electronic device of claim 1, wherein the first groove extends in a width direction of the window, and
the second groove extends in the width direction of the window.

3. The electronic device of claim 1, wherein the first groove comprises a first inclined surface and a second inclined surface, and
the second groove comprises a third inclined surface that comprises a shape substantially the same as a shape of the first inclined surface and is disposed on the window and a fourth inclined surface that comprises a shape substantially the same as a shape of the second inclined surface and is disposed on the housing.

4. The electronic device of claim 3, wherein the first inclined surface and the second inclined surface are disposed to be mirror-symmetrical with each other, and
the third inclined surface and the fourth inclined surface are disposed to be mirror-symmetrical with each other.

5. The electronic device of claim 1, wherein the window further comprises a first fixed pole protruding from an inner surface of the window, and
the housing further comprises a first socket configured to fix the first fixed pole.

6. The electronic device of claim 5, wherein the window further comprises a second fixed pole protruding from the inner surface of the window and spaced apart from the first fixed pole, and
the housing further comprises a second socket on which the second fixed pole is disposed.

7. The electronic device of claim 1, further comprising:
an adhesive layer at least partially disposed on an inner surface of the window and spaced apart from the key area.

8. The electronic device of claim 1, further comprising:
a switch disposed to correspond to the key area and configured to generate an electrical signal associated with heating or a state of a device.

9. The electronic device of claim 8, further comprising:
a seal disposed between the switch and the key area and configured to be elastically deformed.

10. The electronic device of claim 1, further comprising:
a mask pad disposed between the housing and the window and elastically deformable.

11. The electronic device of claim 1, wherein the housing further comprises a recessed sheet toward an inside of the housing, and
the sheet defines a recess on which at least a portion of the window is disposed.

12. The electronic device of claim 1, wherein an outer surface of the window and at least a portion of an outer surface of the housing are on a substantially same plane.

13. The electronic device of claim 1, wherein the key area comprises a design element which is a logo, a character, a symbol, or a shape, or a combination thereof.

14. The electronic device of claim 1, wherein the first groove comprises a first edge that is perpendicular to an outer surface of the window and a second edge that is perpendicular to the outer surface of the window, and
the second groove comprises a third edge that comprises a shape substantially the same as a shape of the first edge and is disposed on the window and a fourth edge that comprises a shape substantially the same as a shape of the second edge and is disposed on the housing.

15. The electronic device of claim 1, wherein the first groove comprises a first round surface and a second round surface, and
the second groove comprises a third round surface that comprises a shape substantially the same as a shape of the first round surface and is disposed on the window and a fourth round surface that comprises a shape substantially the same as a shape of the second round surface and is disposed on the housing.
